(19) United States
(12) Patent Application Publication
(10) Pub. No.: US 2016/0172238 A1
(43) Pub. Date: Jun. 16, 2016

(54) SELECTIVE SEALANT REMOVAL

(71) Applicant: Applied Materials, Inc., Santa Clara, CA (US)

(72) Inventors: Bhaskar Kumar, Santa Clara, CA (US); Deenesh Padhi, Sunnyvale, CA (US); Alexandros T. Demos, Dublin, CA (US); Tapash Chakraborty, Powai (IN); Geetika Bajaj, New Delhi (IN); Robert Jan Visser, Menlo Park, CA (US)

(73) Assignee: APPLIED MATERIALS, INC., Santa Clara, CA (US)

(21) Appl. No.: 14/569,301

(22) Filed: Dec. 12, 2014

(51) Int. Cl. H01L 21/768

(52) U.S. Cl. CPC H01L 21/76831; H01L 21/76877

(57) ABSTRACT

A method of forming features in a low-k dielectric layer is described. A via, trench or a dual damascene structure may be present in the low-k dielectric layer prior to depositing a conformal hermetic layer. The conformal hermetic layer is configured to keep water and contaminants out. Some of the same conformal hermetic layer may deposit on the underlying copper. The portion of the conformal hermetic layer on the underlying copper is preferentially removed but the beneficial portion on the low-k dielectric layer remains. The selective removal of the conformal hermetic layer may be accomplished using a dry etch or a wet etch using a weak organic acid.

### FIELD

Embodiments of the invention relate to forming and protecting low-k dielectrics.

### BACKGROUND

Low-k dielectrics are those having a smaller dielectric constant than silicon dioxide (SiO₂). Silicon dioxide has a dielectric constant of 3.9. Low-k dielectric materials are positioned between conducting elements in integrated circuits to improve achievable switching speed and reduce power consumption as feature sizes are decreased. Low-k dielectric films are achieved by selecting film materials which reduce dielectric constant and/or inserting pores inside the film.

Besides decreasing the dielectric constant, the conductivity of the conducting elements (e.g. metal lines) can be increased. As a consequence, copper has replaced many other metals for longer lines (interconnects). Copper has a lower resistivity and higher current carrying capacity. However, precautions must be taken to discourage diffusion of copper into surrounding materials. Besides the need to inhibit diffusion into active semiconductor areas, copper should be kept from entering porous low-k dielectric regions to avoid shorting and maintain the low dielectric constant.

An example of an integrated circuit structure which implements copper as an interconnect material is a dual damascene structure. In a dual damascene structure, the dielectric layer is etched to define both the contacts/vias and the interconnect lines. Metal is inlaid into the defined pattern and any excess metal is removed from the top of the structure in a planarization process, such as chemical mechanical polishing (CMP).

Novel liner layers and/or process modifications are needed to achieve high conductivity for the interconnect connections in combination with a low-k for the dielectric material.

### SUMMARY

A method of forming features in a low-k dielectric layer is described. A via, trench or a dual damascene structure may be present in the low-k dielectric layer prior to depositing a conformal hermetic layer. The conformal hermetic layer is configured to keep water and contaminants out. Some of the same conformal hermetic layer may deposit on the underlying copper. The portion of the conformal hermetic layer on the underlying copper is preferentially removed but the beneficial portion on the low-k dielectric layer remains. The selective removal of the conformal hermetic layer may be accomplished using a dry etch or a wet etch using a weak organic acid.

Embodiments of the invention include methods of forming patterned low-k dielectric. The methods include forming a conformal hermetic layer on a patterned substrate. The patterned substrate includes a gap above an underlying metal layer. A first portion of the conformal hermetic layer is formed on the underlying metal layer and a second portion of the conformal hermetic layer is formed on dielectric sidewalls of the gap. The methods further include removing the first portion of the conformal hermetic layer while retaining the second portion of the conformal hermetic layer. The methods further include depositing gapfill copper into the gap to form a conducting contact between the gapfill copper and the underlying metal layer.

Embodiments of the invention include methods of forming a gap in a low-k dielectric layer. The methods include forming a conformal silicon-and-carbon-containing layer on a patterned substrate. The patterned substrate comprises a gap above an underlying copper layer. Sidewalls of the gap comprise low-k dielectric material. The conformal silicon-and-carbon-containing layer is configured to prevent diffusion of material into the low-k dielectric material. The methods further include removing the conformal silicon-and-carbon-containing layer from the underlying copper layer but not from the sidewalls. The methods further include depositing a conductor into the gap to form an ohmic contact between the conductor and the underlying copper layer.

Embodiments of the invention include methods of forming a dual damascene structure. The methods include forming a conformal silicon carbon nitride layer over a patterned substrate. The patterned substrate includes a trench and a via below the trench. The via is above an underlying copper layer. Sidewalls of the trench and the via include low-k dielectric walls. The trench is fluidly coupled to the via and the conformal silicon carbon nitride layer forms a hermetic seal between the trench and the low-k dielectric walls. The methods further include selectively removing the conformal silicon carbon nitride layer from the underlying copper layer while retaining the conformal silicon carbon nitride layer on the low-k dielectric walls. Selectively removing the conformal silicon carbon nitride layer includes exposing the conformal silicon carbon nitride layer to a liquid weak organic acid.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the embodiments may be realized by reference to the remaining portions of the specification and the drawings.

FIG. 1 is a flow chart of a selective sealant removal process according to embodiments.

FIGS. 2A, 2B and 2C show cross-sectional views of a device at stages of a selective sealant removal process according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

A method of forming features in a low-k dielectric layer is described. A via, trench or a dual damascene structure may be present in the low-k dielectric layer prior to depositing a conformal hermetic layer. The conformal hermetic layer is configured to keep water and contaminants out. Some of the same conformal hermetic layer may deposit on the underlying copper. The portion of the conformal hermetic layer on the underlying copper is preferentially removed but the beneficial portion on the low-k dielectric layer remains. The selective removal of the conformal hermetic layer may be accomplished using a dry etch or a wet etch using a weak organic acid.

Copper damascene and dual-damascene structures have been used for several decades and involve depositing copper into gaps in a patterned low-k dielectric layer. Dual damascene structures include two distinct patterns formed into a dielectric layer. The lower pattern may include via structures whereas the upper pattern may include a trench. The via and the trench are filled at the same time which is the operation for which the dual-damascene process gets its name. The dielectric constant of the low-k dielectric layer may be undesirably increased during subsequent processing so a conformal hermetic layer may be deposited covering both the patterned low-k dielectric layer and the exposed underlying copper layer.

The portion of the conformal hermetic layer covering the patterned low-k dielectric layer is desirable. On the other hand, the portion of the conformal hermetic layer covering the underlying copper layer may decrease the net conductivity of the electric pathway between the underlying copper layer and an overlying metal layer. The methods described herein have been developed to selectively remove the portion of the conformal hermetic layer covering the underlying copper layer while retaining the desirable portion of the conformal hermetic layer covering the patterned low-k dielectric layer. The selectivity may or may not arise from morphological difference between the deposition of thin hermetic layers on the two types of surfaces. The methods described herein provide the benefit of increasing conductivity and performance of completed devices. An additional benefit is the achievement and maintenance of low dielectric constant in the patterned low-k dielectric layer which also increases performance of completed devices (e.g. higher switching speeds or lower power consumption).

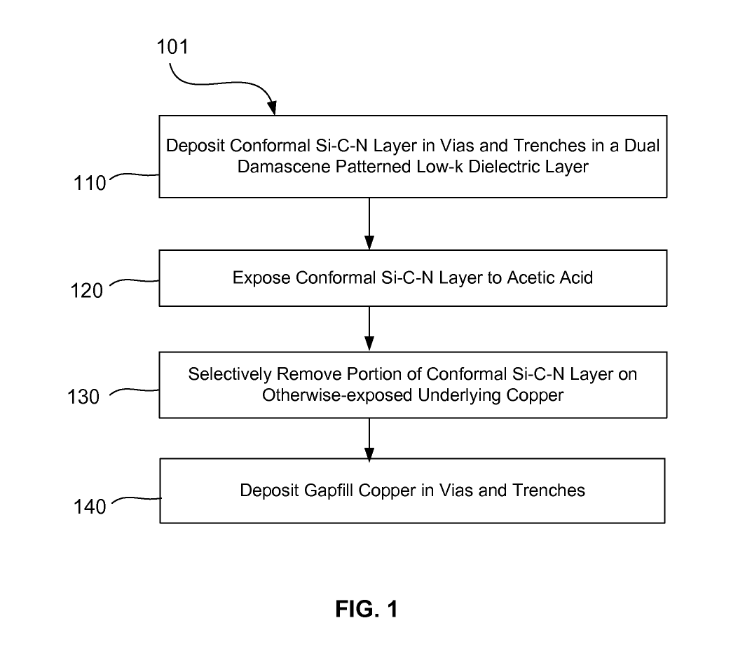

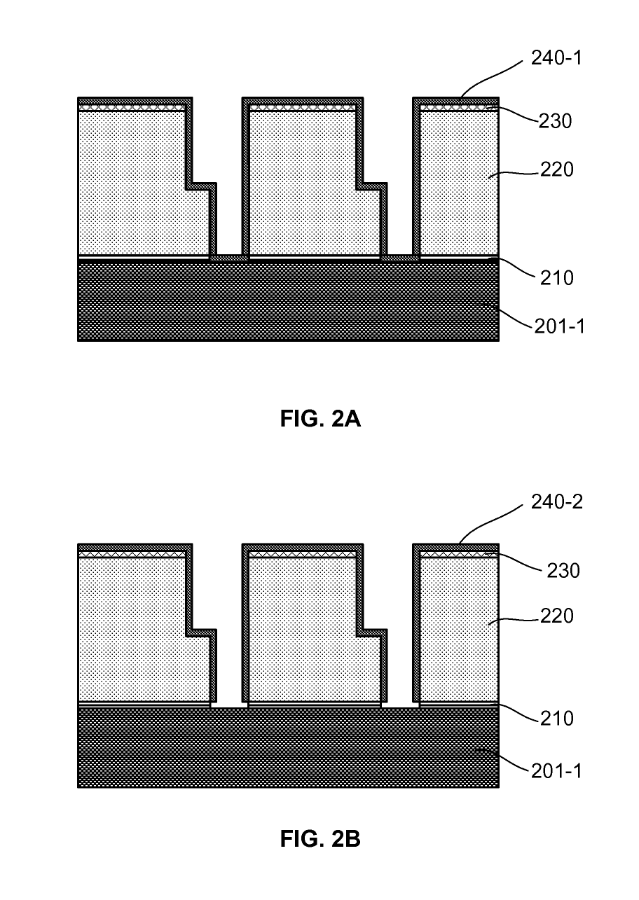

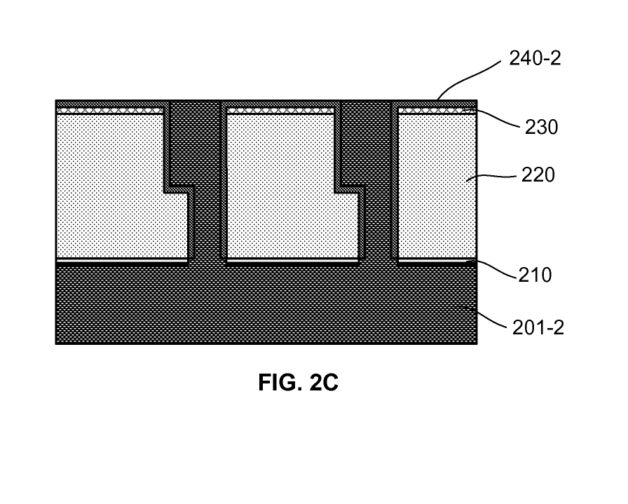

In order to better understand and appreciate the invention, reference is now made to FIG. 1 which is a selective sealant removal process 101 according to embodiments. Concurrently, reference will be made to FIGS. 2A, 2B and 2C which show cross-sectional views of a device at various stages of selective sealant removal process 101. The portion of the device shown may be a back-end of the line (BEOL) interconnect portion of an integrated circuit during formation in embodiments. Prior to the first operation (FIG. 2A), an exposed titanium nitride layer is formed, patterned into titanium nitride hardmask 230, and used to pattern an underlying low-k dielectric layer 220 on the patterned substrate. A copper barrier dielectric layer 210 may be used to physically separate underlying copper layer 201-1 from low-k dielectric layer 220. Underlying copper layer 201-1 is located beneath the low-k dielectric layer and is exposed to the atmosphere through the combination of the via and the trench. Generally speaking, underlying copper layer 201-1 may be an underlying metal layer.

Low-k dielectric layer 220 may have pores within the film to achieve a lower dielectric constant than silicon oxide. Low-k dielectric layer 220 may comprise or consist of silicon, carbon and oxygen, in embodiments, to further reduce the dielectric constant below that of silicon oxide. Low-k dielectric layer 220 may therefore be referred to as silicon oxycarbide. Selective sealant removal process 101 has been developed to achieve and maintain a low dielectric constant within low-k dielectric layer 220 during processing and during the active life of the integrated circuit produced.

Titanium nitride hardmask 230 may be physically separated from low-k dielectric layer 220 by an auxiliary hardmask to facilitate processing, though no such layer is shown in FIG. 2A, 2B or 2C. The auxiliary hardmask layer may be a silicon oxide hardmask in embodiments. “Top”, “above” and “up” will be used herein to describe portions/directions perpendicularly distal from the substrate plane and further away from the center of mass of the substrate in the perpendicular direction. “Vertical” will be used to describe items aligned in the “up” direction towards the “top”. Other similar terms may be used whose meanings will now be clear.

A conformal hermetic layer 240-1 is formed on the patterned substrate in operation 110, shown following formation in FIG. 2A. The conformal hermetic layer is conformal over the features of the patterned substrate and contacts underlying copper layer 201-1 directly in embodiments. The conformal hermetic layer may also contact low-k dielectric layer 220 directly according to embodiments. Conformal hermetic layer 240-1 may be a silicon-and-carbon-containing layer in embodiments. Conformal hermetic layer 240-1 may comprise or consist of silicon, carbon and nitrogen, according to embodiments, and may be referred to as silicon carbon nitride or Si—C—N. Conformal hermetic layer 240-1 may inhibit diffusion of subsequently-introduced etchants or moisture and may therefore protect the integrity of low-k dielectric layer 220 during and after processing in embodiments. A copper barrier dielectric layer 210 may be positioned between underlying copper layer and low-k dielectric layer 220 as shown in FIGS. 2A-2C. The deposition process of conformal hermetic layer 240-1 may also result in a lowering of the dielectric constant simply from the displacement of absorbates and other components within low-k dielectric layer 220. Conformal hermetic layer 240-1 (and conformal hermetic layer 240-2 later) may help to avoid diffusion of copper into low-k dielectric layer 220 as well, according to embodiments.

Conformal hermetic layer (e.g. Si—C—N) is exposed to acetic acid in operation 120. Conformal hermetic layer 240-1 is etched back to expose underlying copper layer 201-1 in operation 130, shown following the operation in FIG. 2B. Selective etching operation 130 may involve liquid or gas-phase etchants according to embodiments. A process which uses gas-phase etchants may be referred to herein as a dry-etch and etching operations within a dry-etch may be referred to as dry-etching conformal hermetic layer 240-1. After selective etching operation 130 a portion of conformal hermetic layer 240-1 remains and will be referred to as conformal hermetic layer 240-2 as shown in FIG. 2B. Conformal hermetic layer 240-2 may also be referred to as the remaining portion of conformal hermetic layer 240-1. Conformal hermetic layer 240-2 continues to seal low-k dielectric layer 220 from environmental influences such as subsequently introduced reactants or moisture which may get into pores in low-k dielectric layer 220 and undesirably increase the dielectric constant. Conformal hermetic layer 240-2 may be a “leave-on” film, according to embodiments, which means conformal hermetic layer 240-2 may remain in the completed integrated circuit being formed in selective sealant removal process 101. Therefore, conformal hermetic layer 240-2 may protect against increase in dielectric constant within low-k dielectric layer 220 during subsequent processing but also during the operational life of the completed integrated circuit.

The trench and the via may be filled with a conductor (e.g. copper as in the example) to complete the dual-damascene portion of a semiconductor manufacturing process in operation 140. FIG. 2C shows underlying copper 201-2 modified to extend through both the trench and the via. As a result of operations 120-130, there is no or substantially no thin dielectric interruption which could negatively impact the conductivity within underlying copper 201-2. As a consequence, underlying copper 201-2 is shown as one entity simply extended through the trench and the via. Technically, FIG. 2C shows underlying copper 201-2 after a planarizing chemical mechanical polishing (CMP) operation since the top surface is flush with the low-k dielectric film stack.

Acetic acid was used in the exemplary selective sealant removal process 101. Generally speaking, a mild acid and/or a gas-phase etchant may be used instead of or to augment the acetic acid according to embodiments. The mild acid may be referred to as a weak acid herein. The weak acid may have a pH between 5 and 7 in embodiments. The weak acid may include one or more of acetic acid, citric acid, formic acid or tartaric acid according to embodiments. The weak acid may be a weak organic acid in embodiments. The weak acid may comprise or consist of carbon, hydrogen and oxygen according to embodiments.

The thickness of the conformal hermetic layer should be sufficient to form a hermetic seal configured to keep moisture out of the low-k dielectric layer. The thickness should be less than a threshold amount to enable enough conducting material (e.g. copper) to desirably fill the gaps in the patterned low-k dielectric layer and form conducting contacts. The thickness should also be less than a threshold amount to ensure the portion of the conformal hermetic layer on the underlying copper layer is selectively removable. A first portion of the conformal hermetic layer resides on the underlying copper layer following deposition. A second portion of the conformal hermetic layer resides on the low-k dielectric layer 220, for example on wall of a gap in the patterned low-k dielectric layer following deposition. The thickness of the second portion of the conformal hermetic layer may be greater than 15 Å or greater than 20 Å, according to embodiments, after deposition but before selective removal. The thickness of the second portion of the conformal hermetic layer may be less than 30 Å or less than 40 Å, in embodiments, after deposition but before selective removal.

The dielectric constant of low-k dielectric layer 220 may be between 2.4 and 2.9 prior to depositing the conformal hermetic layer. The conformal hermetic layer may be deposited by UV-assisted chemical vapor deposition (UV-CVD) and the deposition process may result in a reduction of the dielectric constant, possibly by replacing hydroxyl groups on the interior surfaces of pores with methyl groups. The dielectric constant may be reduced by 0.1 simply by depositing conformal hermetic layer 240-1. The dielectric constant may be between 2.3 and 2.8 after deposition but before selective removal.

The selective removal operation may remove the first portion but not the second portion of the conformal hermetic layer. The selective removal operation may expose the underlying copper layer in embodiments. This ensures subsequent capability of achieving a highly conductive connection between the conductor which fills the gaps in the patterned low-k dielectric layer and the underlying copper layer (or, more generally, another underlying metal layer). The contact between the gapfill conductor and the underlying copper layer may be an ohmic contact according to embodiments. The thickness of the second portion of the conformal hermetic layer may be greater than 15 Å or greater than 20 Å, according to embodiments, after the selective removal operation. The thickness of the second portion of the conformal hermetic layer may be less than 30 Å or less than 40 Å, in embodiments, after the selective removal operation. After the selective removal operation, the dielectric constant of the low-k dielectric layer may be between 2.3 and 2.8.

The processes disclosed herein display etch selectivities of the first portion of the conformal hermetic layer relative to the second portion of the conformal hermetic layer. The etch selectivity of the first portion relative to the second portion may be greater than or about 10:1, greater than or about 25:1, greater than or about 50:1 or greater than or about 100:1 in embodiments. These high selectivities may arise from an incomplete coverage of metal surfaces with silicon carbon nitride and other thin low-k dielectric sealants (the conformal hermetic layer). The deposition of the sealant on metals may be patchy whereas the deposition of the sealant on the low-k dielectric may be smooth and hermetic in embodiments. The etch selectivity of the first portion relative to copper or another underlying metal material may be greater than 25:1, greater than 50:1, greater than 100:1 or greater than 250:1 according to embodiments.

The trench and/or via structures lined with the conformal hermetic layer may be a dual-damascene structure including a via underlying a trench. The via may be a low aspect ratio gap and may be, e.g., circular as viewed from above the patterned substrate laying flat. The structure may be at the back end of the line which may result in larger dimensions depending on the device type. A width of the via may be less than 50 nm, less than 40 nm, less than 30 nm or less than 20 nm according to embodiments. A width of the trench may be less than 70 nm, less than 50 nm, less than 40 nm or less than 30 nm in embodiments. The dimensions described herein apply to structures involving a single-patterned low-k dielectric layer or a multi-patterned low-k dielectric layer (e.g. dual-damascene structure). An aspect ratio of the via may be about 1:1, as viewed from above, whereas an aspect ratio of the trench may be greater than 10:1 since the trench is used to contain a conductor meant to electrically attach multiple vias.

During exposing operation 120 and etching operation 130, the substrate may be maintained between −30° C. and about 200° C. in general. The temperature of the patterned substrate during operation 120 and/or 130 may be between −20° C. and 150° C., 10° C. and 200° C., between 20° C. and 75° C. or between 25° C. and 50° C. in embodiments.

The examples described herein involve the preparation of a long trench above a low-aspect ratio via in a dual-damascene structure. Generally speaking the structure may involve only one level and the low-k dielectric layer may have long trenches and/or vias according to embodiments. For the purposes of description herein and claim recitations below, a via is simply a low-aspect ratio gap and so the term “gap” covers all holes in a low-k dielectric described herein. Generally speaking, underlying copper layer 201 may be any underlying conducting layer in embodiments.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon oxide” of the patterned substrate is predominantly SiO₂ but may include concentrations of other elemental constituents such as, e.g., nitrogen, hydrogen and carbon. In some embodiments, silicon oxide portions etched using the methods disclosed herein consist essentially of silicon and oxygen. Exposed “silicon nitride” of the patterned substrate is predominantly Si₃N₄ but may include concentrations of other elemental constituents such as, e.g., oxygen, hydrogen and carbon. In some embodiments, silicon nitride portions described herein consist essentially of silicon and nitrogen. Exposed “titanium nitride” of the patterned substrate is predominantly titanium and nitrogen but may include concentrations of other elemental constituents such as, e.g., oxygen, hydrogen and carbon. In some embodiments, titanium nitride portions described herein consist essentially of titanium and nitrogen. The low-k dielectric may be “silicon oxycarbide” which is predominantly silicon, oxygen and carbon but may include concentrations of other elemental constituents such as, e.g., nitrogen and hydrogen. In some embodiments, silicon oxycarbide portions described herein consist essentially of silicon, oxygen and carbon. Exposed “silicon carbon nitride” of the patterned substrate is predominantly silicon, carbon and nitrogen but may include concentrations of other elemental constituents such as, e.g., oxygen and hydrogen. In some embodiments, silicon carbon nitride portions described herein consist essentially of silicon, carbon and nitrogen. “Copper” of the patterned substrate is predominantly copper but may include concentrations of other elemental constituents such as, e.g., oxygen, nitrogen, hydrogen and carbon. In some embodiments, copper portions described herein consist essentially of copper. Analogous definitions for other metals will be understood from this copper definition.

The term “gap” is used throughout with no implication that the etched geometry has a large horizontal aspect ratio. Viewed from above the surface, gaps may appear circular, oval, polygonal, rectangular, or a variety of other shapes. The term “trench” is defined as a large aspect ratio gap with a long dimension (viewed from above) at least ten times a short dimension (also viewed from above). The long dimension does not have to be linear, e.g., a trench may be in the shape of a moat around an island of material, in which case the long dimension is the circumference. The term “via” is used to refer to a low aspect ratio gap which may or may not be filled with metal to form a vertical electrical connection. As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming patterned low-k dielectric, the method comprising:
forming a conformal hermetic layer on a patterned substrate, wherein the patterned substrate comprises a gap above an underlying metal layer, wherein a first portion of the conformal hermetic layer is formed on the underlying metal layer and a second portion of the conformal hermetic layer is formed on dielectric sidewalls of the gap;
removing the first portion of the conformal hermetic layer while retaining the second portion of the conformal hermetic layer; and
depositing gapfill copper into the gap to form a conducting contact between the gapfill copper and the underlying metal layer.

2. The method of claim 1 wherein the second portion of the conformal hermetic layer is configured to prevent moisture from entering the dielectric sidewalls.

3. The method of claim 1 wherein a thickness of the second portion of the conformal hermetic layer is between 15 Å and 40 Å following the operation of removing the first portion of the conformal hermetic layer.

4. The method of claim 1 wherein the conformal hermetic layer comprises silicon, carbon and nitrogen.

5. A method of forming a gap in a low-k dielectric layer, the method comprising:
forming a conformal silicon-and-carbon-containing layer on a patterned substrate, wherein the patterned substrate comprises a gap above an underlying copper layer, wherein sidewalls of the gap comprise low-k dielectric material, wherein the conformal silicon-and-carbon-containing layer is configured to prevent diffusion of material into the low-k dielectric material;
removing the conformal silicon-and-carbon-containing layer from the underlying copper layer but not from the sidewalls; and
depositing a conductor into the gap to form an ohmic contact between the conductor and the underlying copper layer.

6. The method of claim 5 wherein the operation of removing the conformal silicon-and-carbon-containing layer exposed the underlying copper layer.

7. The method of claim 5 wherein the operation of removing the conformal silicon-and-carbon-containing layer comprises exposing the conformal silicon-and-carbon-containing layer to a weak acid.

8. The method of claim 7 wherein the weak acid is selected from the group consisting of acetic acid, citric acid, formic acid and tartaric acid.

9. The method of claim 5 wherein a width of the gap is less than 20 nm.

10. The method of claim 5 wherein the operation of forming the conformal silicon-and-carbon-containing layer comprises dry-etching the conformal silicon-and-carbon-containing layer.

11. The method of claim 5 wherein the conformal silicon-and-carbon-containing layer consists of silicon, carbon and nitrogen.

12. A method of forming a dual damascene structure, the method comprising:
forming a conformal silicon carbon nitride layer over a patterned substrate, wherein the patterned substrate comprises a trench and a via below the trench, wherein the via is above an underlying copper layer, wherein sidewalls of the trench and the via comprise low-k dielectric walls, and wherein the trench is fluidly coupled to the via and the conformal silicon carbon nitride layer forms a hermetic seal between the trench and the low-k dielectric walls; and
selectively removing the conformal silicon carbon nitride layer from the underlying copper layer while retaining the conformal silicon carbon nitride layer on the low-k dielectric walls, wherein selectively removing the conformal silicon carbon nitride layer comprises exposing the conformal silicon carbon nitride layer to a liquid weak organic acid.

13. The method of claim 12 wherein a pH of the liquid weak organic acid is between 5 and 7.

14. The method of claim 12 wherein a width of the via is less than 50 nm.

15. The method of claim 12 wherein a width of the trench is less than 70 nm.
